(19) United States
(12) Patent Application Publication
(10) Pub. No.: US 2016/0252938 A1
(43) Pub. Date: Sep. 1, 2016

(54) DEVICE AND MEMORY CONTROL METHOD

(71) Applicant: FUJITSU LIMITED, Kawasaki-shi (JP)

(72) Inventor: Kazuaki OISHI, Yokohama (JP)

(73) Assignee: FUJITSU LIMITED, Kawasaki-shi (JP)

(21) Appl. No.: 15/016,637

(22) Filed: Feb. 5, 2016

(30) Foreign Application Priority Data
Feb. 26, 2015 (JP) 2015-036567

(51) Int. Cl. G06F 1/26; G11C 5/14; G06F 3/06; G11C 14/00

(52) U.S. Cl. CPC G06F 1/26; G11C 14/0063; G11C 5/148; G06F 3/0617; G06F 3/0653; G06F 3/0685

(57) ABSTRACT

A device includes: a nonvolatile memory configured to store data; a volatile memory configured to store the data read out from the nonvolatile memory; a processor configured to perform processing using the data stored in the volatile memory; and a measurement circuit configured to measure standby power of the volatile memory when the power of the volatile memory is turned on, wherein the processor is configured to control, based on a measurement result outputted from the measurement circuit, power supply to the volatile memory while the processor is to be intermittently operated.

### CROSS-REFERENCE TO RELATED APPLICATION

This application is based upon and claims the benefit of priority of the prior Japanese Patent Application No. 2015-036567, filed on Feb. 26, 2015, the entire contents of which are incorporated herein by reference.

### FIELD

The embodiments discussed herein are related to a device and a memory control method.

### BACKGROUND

In recent years, a semiconductor integrated circuit device on which a micro control unit (MCU) core, a nonvolatile memory, and a volatile memory are mounted has been provided and widely used in various electronic devices, such as, for example, a wireless sensor network terminal device and the like.

The wireless sensor network terminal measures (collects) various types of information including a temperature, a humidity, and the like, using, for example, a sensor, and intermittently transmits the measured information to a base station through wireless communication.

In this case, for example, in accordance with whether temperature information measured by the sensor changes over time moderately or abruptly, a communication interval of communication between the wireless sensor network terminal and the base station changes.

That is, when measurement data moderately changes over time, the communication interval is preferably increased to reduce power consumption, while, if the measurement data abruptly changes over time, the communication interval is preferably reduced to precisely measure changes.

Conventionally, for example, as a semiconductor integrated circuit device in which an intermittent operation is performed, a wireless sensor network terminal, and a memory control method for a semiconductor integrated circuit device, various proposals have been made.

As examples of related art, technologies described in Japanese Laid-open Patent Publication No. 2013-215976 and Japanese Laid-open Patent Publication No. 2009-230172 have been known.

### SUMMARY

According to an aspect of the invention, a device includes: a nonvolatile memory configured to store data; a volatile memory configured to store the data read out from the nonvolatile memory; a processor configured to perform processing using the data stored in the volatile memory; and a measurement circuit configured to measure standby power of the volatile memory when the power of the volatile memory is turned on, wherein the processor is configured to control, based on a measurement result outputted from the measurement circuit, power supply to the volatile memory while the processor is to be intermittently operated.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an example semiconductor integrated circuit device;

FIG. 2 is a block diagram illustrating another example semiconductor integrated circuit device;

FIG. 3 is a block diagram illustrating an example wireless sensor network terminal to which the semiconductor integrated circuit device illustrated in FIG. 2 is applied;

FIG. 4A to FIG. 4C are charts illustrating an example of intermittent operation performed in a wireless sensor network;

FIG. 5 is a chart illustrating power consumption in an example of intermittent operation of the wireless sensor network terminal illustrated in FIG. 3;

FIG. 6 is a block diagram illustrating another example of intermittent operation of the wireless sensor network terminal illustrated in FIG. 3;

FIG. 7 is a chart illustrating power consumption in the another example of intermittent operation of the wireless sensor network terminal illustrated in FIG. 6;

FIG. 8A and FIG. 8B are charts illustrating the relationships between the operation of the wireless sensor network terminal and power consumption illustrated in FIG. 5 and FIG. 7;

FIG. 9 is a block diagram illustrating a wireless sensor network terminal to which a semiconductor integrated circuit device according to a first embodiment is applied;

FIG. 10A and FIG. 10B are charts illustrating an operation of the wireless sensor network terminal illustrated in FIG. 9;

FIG. 11 is a block diagram illustrating an example volatile memory standby power measurement circuit in the semiconductor integrated circuit device illustrated in FIG. 9;

FIG. 12 is a circuit diagram illustrating the example volatile memory standby power measurement circuit illustrated in FIG. 11;

FIG. 13 is a block diagram illustrating a wireless sensor network terminal to which a semiconductor integrated circuit device according to a second embodiment is applied;

FIG. 14 is a block diagram illustrating an example volatile memory standby power measurement circuit in the semiconductor integrated circuit device illustrated in FIG. 13; and

FIG. 15 is a circuit diagram illustrating the example volatile memory standby power measurement circuit illustrated in FIG. 14.

### DESCRIPTION OF EMBODIMENTS

A wireless sensor network terminal in which an intermittent operation is performed is normally driven by a battery, and therefore, it is desired that, for example, even when a communication interval of communication with a base station changes, the wireless sensor network terminal performs control in accordance with the change to reduce power consumption.

Thus, for example, it has been proposed that, in the wireless sensor network terminal, when a communication operation with a base station is terminated, powers of an MCU core, a nonvolatile memory, and a volatile memory are turned off to reduce power consumption.

In this case, data (a program) held in the volatile memory is erased by turning off the power of the volatile memory, and thus, for next and subsequent communication operations with a base station, each time a communication operation is performed, the program is read out from the nonvolatile memory to the volatile memory. That is, each time a communication operation is performed, memory access power for reading out the program from the nonvolatile memory to the volatile memory is consumed.

Also, it may be proposed that, if, while the power of the volatile memory is maintained in an on state, next and subsequent communication operations with a base station are performed, a program held in the volatile memory is used as it is to reduce the memory access power. However, in this case, power (standby power) is consumed by maintaining the power of the volatile memory in an on state.

Incidentally, the standby power of the volatile memory largely changes due to fabrication variations of a semiconductor integrated circuit device, environmental variations, such as variations in the temperature of an area surrounding a place in which a wireless sensor network terminal is placed, and the like, and it is difficult to predict the standby power.

Therefore, in a semiconductor integrated circuit device which includes an MCU core, a nonvolatile memory, and a volatile memory and is configured such that the MCU core executes a program read out from the nonvolatile memory to the volatile memory, it is difficult to perform memory control in an intermittent operation with low power consumption.

According to an aspect of an embodiment, a semiconductor integrated circuit, a wireless sensor network terminal, and a memory control method that are disclosed herein may allow reduction in power consumption for an intermittent operation.

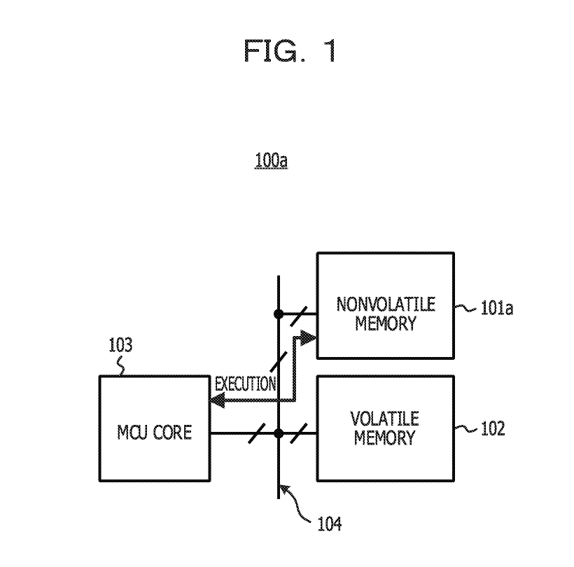

First, before describing this embodiment, with reference to FIG. 1 to FIG. 8, examples of a semiconductor integrated circuit and a semiconductor integrated circuit device, a wireless sensor network terminal to which the semiconductor integrated circuit is applied, and problems thereof will be described.

FIG. 1 is a block diagram illustrating an example semiconductor integrated circuit device. As illustrated in FIG. 1, a semiconductor integrated circuit device 110a includes a nonvolatile memory 101a, a volatile memory 102, a micro control unit (MCU) core 103, and a bus 104. The MCU core will be hereinafter referred to as a processor occasionally.

In the semiconductor integrated circuit device 110a illustrated in FIG. 1, for example, the nonvolatile memory 101a is a NOR-type flash memory, and the volatile memory 102 is a static random access memory (SRAM). Also, the nonvolatile memory 101a, the volatile memory 102, and the MCU core 103 are coupled to one another via the bus 104.

A case where the MCU core 103 executes a program stored in the nonvolatile memory 101a will be discussed below. In this case, the nonvolatile memory 101a, which is a NOR-type flash memory, may be randomly accessed, and therefore, the MCU core 103 may execute the program directly on the nonvolatile memory 101a.

That is, if a NOR-type flash memory is used as the nonvolatile memory 101a, processing of reading out a program from the nonvolatile memory 101a to the volatile memory 102 or processing of writing contents of the volatile memory 102 to the nonvolatile memory 101a is not performed, so that power consumption is reduced.

However, for example, in order to employ a NOR-type flash memory, a high cost flash memory mixed process is used for fabricating the NOR-type flash memory, and therefore, it is difficult to provide a semiconductor integrated circuit device at low price. Also, unlike a NAND-type flash memory, a NOR-type flash memory is not suitable for high integration (large capacity), and therefore, there are cases where a NOR-type flash memory is not selected for use in view of storage capacity.

In another case, even in the nonvolatile memory 101a of a NOR-type flash memory, the operation speed is far lower than that of the volatile memory 102 of an SRAM, and therefore, for example, when high speed program execution is desired, a program is read out to the volatile memory 102 once, and then, the program is executed.

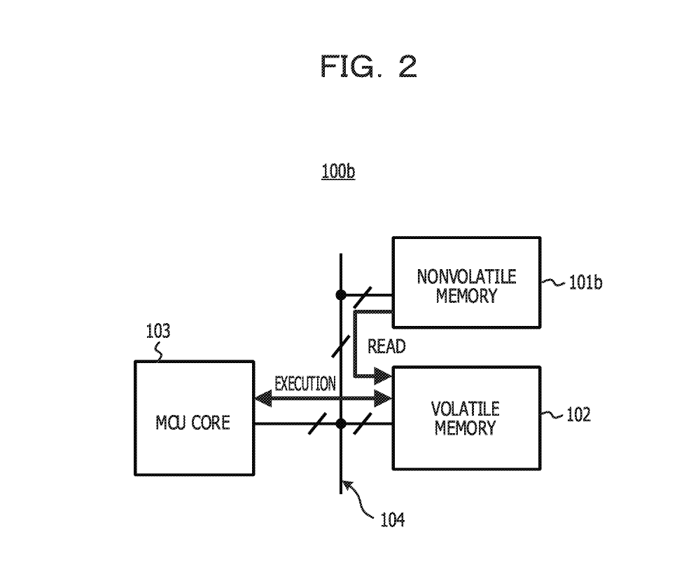

FIG. 2 is a block diagram illustrating another example semiconductor integrated circuit device. As illustrated in FIG. 2, a semiconductor integrated circuit device 110b has a configuration obtained by replacing the nonvolatile memory with a NAND-type flash memory (101b) in the semiconductor integrated circuit device 110a illustrated in FIG. 1, which has been described above. Note that, similar to FIG. 1, the nonvolatile memory 101b of a NAND-type flash memory, the volatile memory 102 of an SRAM, and the MCU core 103 are coupled to one another via the bus 104.

In this case, since random access to a NAND-type flash memory is difficult, a program stored in the nonvolatile memory 101b of a NAND-type flash memory is read out via the bus 104 and is written to (held in) the volatile memory 102. Then, the MCU core 103 executes the program on the volatile memory 102.

As described above, when the program stored in the nonvolatile memory 101b is read out to the volatile memory 102 and is held therein and the MCU core 103 executes the program on the volatile memory 102, power is consumed by reading out and holding (writing) the program.

Also, as described above, even in the nonvolatile memory 101a of a NOR-type flash memory, when high speed program execution is desired, and the like, similarly, a program is read out to the volatile memory 102, so that power consumption is increased.

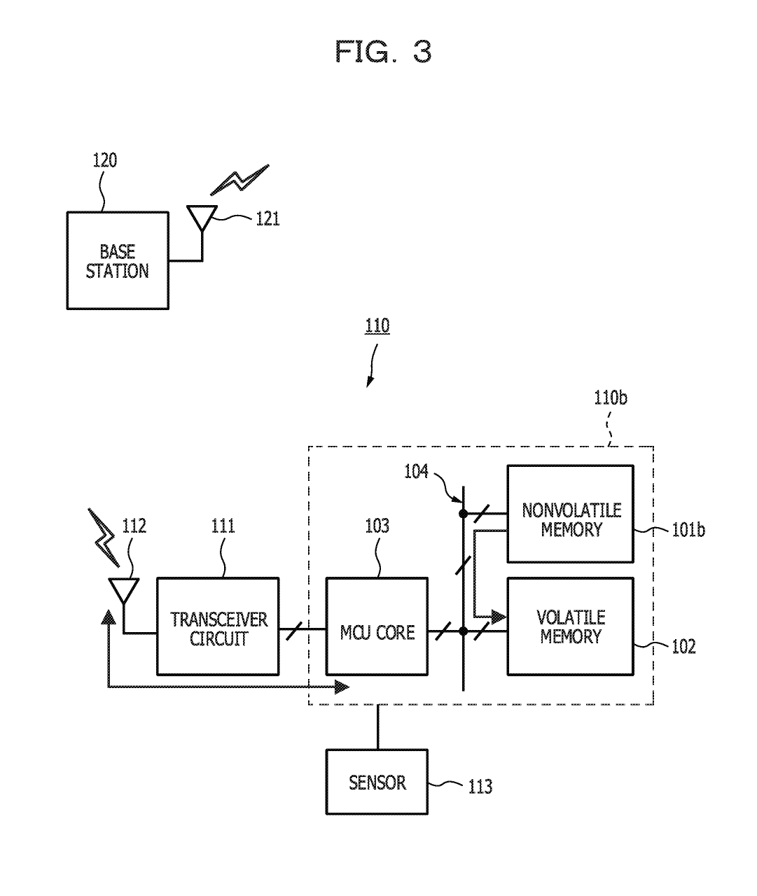

FIG. 3 is a block diagram illustrating an example wireless sensor network terminal to which the semiconductor integrated circuit device illustrated in FIG. 2 is applied, and illustrates a wireless sensor network terminal 110 to which the semiconductor integrated circuit device 110b illustrated in FIG. 2 is applied with a base station 140. In FIG. 3, the reference character 111 denotes a transceiver circuit, each of the reference characters 112 and 141 denotes an antenna, and the reference character 113 denotes a sensor.

In this case, the wireless sensor network includes, for example, a single base station 140 and a plurality of wireless sensor network terminals 110 and transmits information measured (collected) by a sensor 113 provided in each of the wireless sensor network terminals 110 to the base station 140 through wireless communication. Note that, as information measured by the sensor 113, there may be various types of information, including a temperature and a humidity.

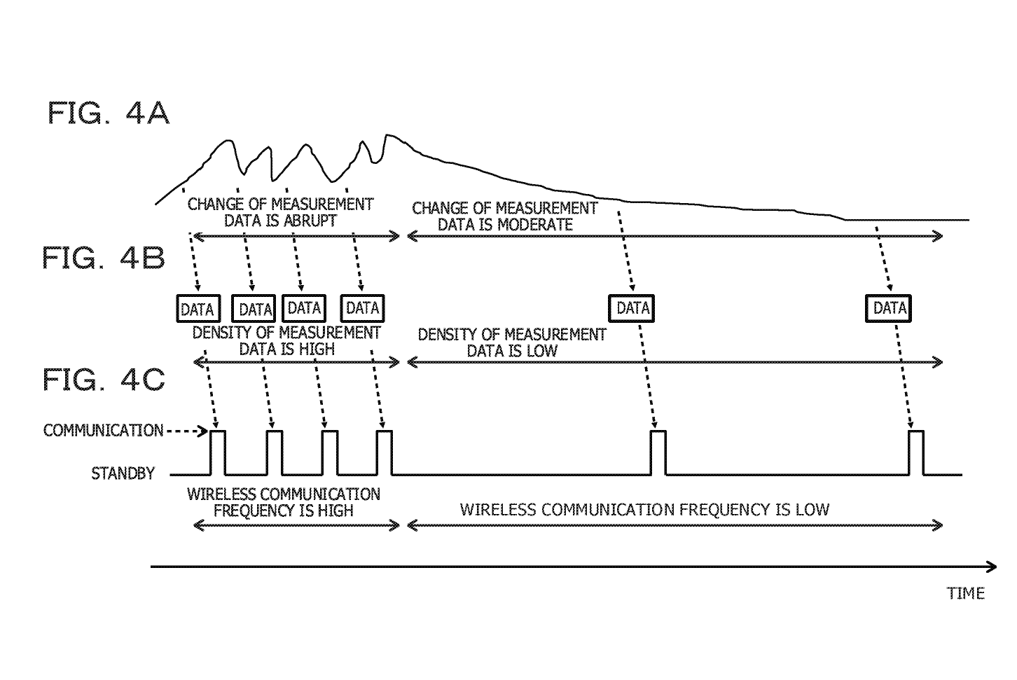

FIG. 4A to FIG. 4C are charts illustrating an example of intermittent operation performed in a wireless sensor network. FIG. 4A illustrates change in information (measurement data) measured by the sensor 113, FIG. 4B illustrates the density of measurement data, and FIG. 4C illustrates the frequency of wireless communication performed by a transceiver circuit 111 with the base station 140.

As illustrated in FIG. 4A, if change in measurement data is abrupt over time (in the left side part of FIG. 4A), as illustrated in FIG. 4B, the density of measurement data is high and, as a result, as illustrated in FIG. 4C, the frequency of wireless communication is increased. That is, for example, if the measurement data acquired by the wireless sensor network terminal 110 abruptly changes over time, an interval of wireless communication performed with the base station 140 is short.

On the other hand, if change in the measurement data is moderate over time (in the central part and the right side part), the density of the measurement data is low and, as a result, the frequency of wireless communication is reduced. That is, if the measurement data acquired by the wireless sensor network terminal 110 moderately changes over time, the interval of wireless communication performed with the base station 140 may be long.

In this case, the wireless sensor network terminal 110 is driven, for example, by a battery, and therefore, if the measurement data moderately changes over time, it is preferable to reduce power consumption by increasing a communication interval.

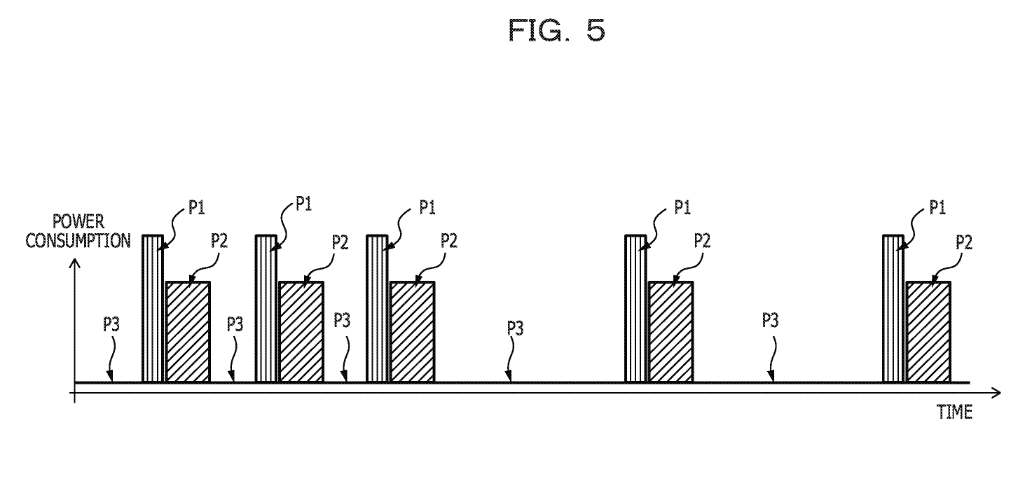

FIG. 5 is a chart illustrating power consumption in an example of intermittent operation of the wireless sensor network terminal illustrated in FIG. 3, and illustrates a case where, each time the MCU core 103 executes the program, a program is read out from the nonvolatile memory 101b to the volatile memory 102 and is held therein.

In FIG. 5, the reference character P1 denotes power (memory access power) used when a program stored in the nonvolatile memory 101b is read out and written to (held in) the volatile memory 102. Note that it is needless to say that what is read out from the nonvolatile memory 101b to the volatile memory 102 is not limited to a program and may be, for example, setting data for a system or the like.

Also, the reference character P2 denotes power (operation power) used for, for example, execution of a program held in the volatile memory 102 by the MCU core 103, wireless communication performed by the transceiver circuit 111 with the base station 140, and the like. Furthermore, the reference character P3 denotes power (sleep power) used when the power of the semiconductor integrated circuit device 110b is shut down and is thus put in a sleep state, and the sleep power is very small power.

Note that the sleep state herein is a state where, for example, all of the powers of the nonvolatile memory 101b, the volatile memory 102, and the MCU core 103 are turned off, and is distinguished from a standby state where the volatile memory 102 is maintained in an on state, which will be described later, when being used.

That is, in a sleep state, the power of the volatile memory 102 is turned off, and therefore, data (a program) held in the volatile memory 102 disappears, while, in a standby state, the power of the volatile memory 102 is maintained in an on state, and therefore, data in the volatile memory 102 is continuously held as it is.

As illustrated in FIG. 5, for example, when a program is read out from the nonvolatile memory 101b to the volatile memory 102 and is processed and a measurement result of the sensor 113 is transmitted to the base station 140, power (P1+P2) during an operation and power P3 during a sleep state are alternately consumed each time.

Accordingly, in the case of FIG. 5, each time a measurement result of the sensor 113 is transmitted to the base station 140, the memory access power P1 and the operation power P2 are consumed and in a state (a sleep state) other than that, only the sleep power P3, which is very small power, is consumed.

That is, in a sleep state where the power of the semiconductor integrated circuit device 110b is shut down (turned off), the program held in the volatile memory 102 is erased, and therefore, when an operation is started next, the program is read out from the nonvolatile memory 101b to the volatile memory 102 again.

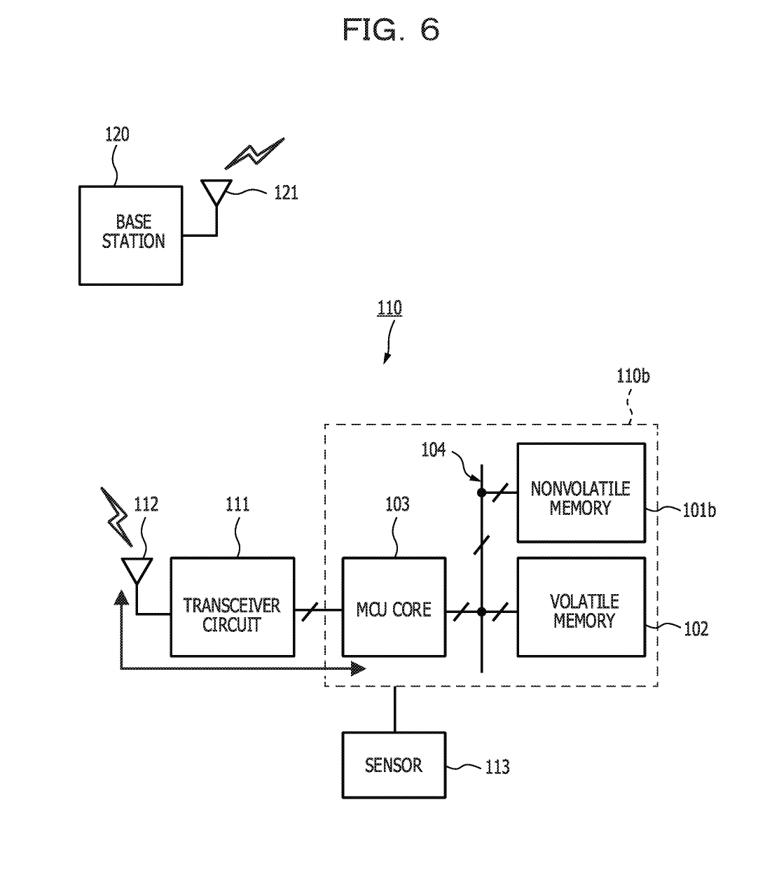

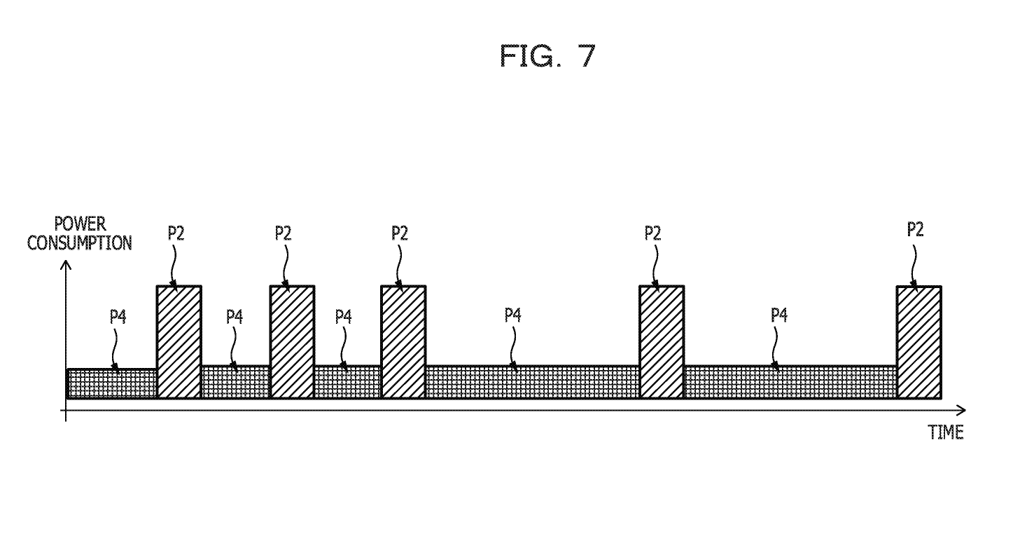

FIG. 6 is a block diagram illustrating another example of intermittent operation of the wireless sensor network terminal illustrated in FIG. 3, and FIG. 7 is a chart illustrating power consumption in the another example of intermittent operation of the wireless sensor network terminal illustrated in FIG. 6.

The intermittent operation of the wireless sensor network terminal illustrated in FIG. 6 and FIG. 7 is an intermittent operation that includes, after a program has been read out from the nonvolatile memory 101b to the volatile memory 102, a standby state where the power of the volatile memory 102 is maintained in an on state, even after communication with the base station 140 has been performed.

In this case, in a standby state, for example, the powers of the nonvolatile memory 101b and the MCU core 103 are turned off, but the power of the volatile memory 102 is maintained in an on state, and the program stored in the volatile memory 102 is continuously held as it is.

That is, as clearly understood from comparison between FIG. 6 and FIG. 3, when the intermittent operation includes a standby state, a program is read out from the nonvolatile memory 101b to the volatile memory 102 once, and then, the program held in the volatile memory 102 is also used in a next operation without erasing the program.

In FIG. 7, the reference character P4 denotes power consumption (standby power) of the volatile memory 102 by maintaining the power of the volatile memory 102 in an on state. That is, the standby power P4 is power used when the powers of the nonvolatile memory 101b and the MCU core 103 are turned off and only the volatile memory 102 is put in an on state.

As illustrated in FIG. 7, when the intermittent operation includes a standby state where the power of the volatile memory 102 is maintained in an on state, that is, for example, when a measurement result of the sensor 113 is transmitted to the base station 140, the memory access power P1, which has been described with reference to FIG. 5, is no longer used.

That is, in a standby state, the program held in the volatile memory 102 is continuously held, and therefore, when a next operation is started, the program held in the volatile memory 102 may be executed as it is.

Note that, in FIG. 7, processing of reading out a program from the nonvolatile memory 101b to the volatile memory 102 during an initial operation is omitted. That is, when a measurement result of the sensor 113 is transmitted to the base station 140 for the first time, a program is not stored in the volatile memory 102, and therefore, the memory access power P1 for reading out a program from the nonvolatile memory 101b to the volatile memory 102 is consumed.

As illustrated above, in the case of FIG. 7, in second and subsequent operations, the program is held in the volatile memory 102, and therefore, the memory access power P1 is not used, and only the operation power P2 is consumed. However, in a standby state, the power of the volatile memory 102 is maintained in an on state, and therefore, predetermined standby power P4 is consumed.

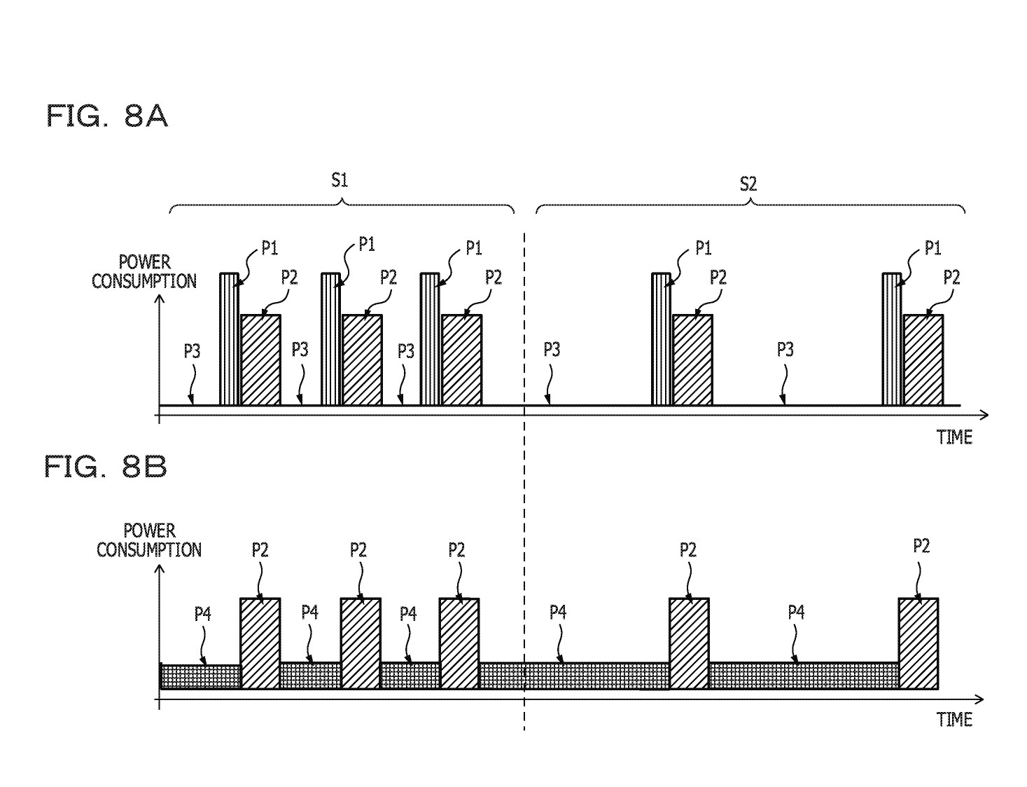

FIG. 8A and FIG. 8B are charts illustrating comparison between the relationships between the operation of the wireless sensor network terminal and power consumption, which are illustrated in FIG. 5 and FIG. 7, FIG. 8A corresponds to FIG. 5, and FIG. 8B corresponds to FIG. 7.

Note that, in FIG. 8A and FIG. 8B, the reference character S1 denotes a case where operation frequency (the frequency of wireless communication with the base station 140) is high over time, and the reference character S2 denotes a case where the operation frequency is low over time.

First, as indicated by S1 in each of FIG. 8A and FIG. 8B, if the operation frequency is high over time, (average) power consumption P1+P2+P3 in FIG. 8A is larger than (average) power consumption P4+P2 in FIG. 8B.

That is, it is understood that, if the wireless communication frequency is high (a communication interval is short), the average power is smaller when the power of the volatile memory 102 is put in an on state and thus a program is held therein than when the program is read out from the nonvolatile memory 101b to the volatile memory 102 each time communication is performed.

On the other hand, as indicated by S2 in each of FIG. 8A and FIG. 8B, if the operation frequency is low over time, the average power consumption P1+P2+P3 in FIG. 8A is smaller than the average power consumption P4+P2 in FIG. 8B.

That is, it is understood that, if the wireless communication frequency is low (a communication interval is long), the average power is smaller when the program is read out from the nonvolatile memory 101b to the volatile memory 102 each time communication is performed than when the power of the volatile memory 102 is put in an on state and a program is held therein.

Incidentally, power consumption based on a leakage current generated when the standby power P4 of the volatile memory 102, that is, the power of the volatile memory 102, is maintained in an on state largely changes due to fabrication variations of the volatile memory 102 (the semiconductor integrated circuit device 110b), environmental variations, and the like, and it is difficult to predict the power consumption. Note that the environmental variations are variations in temperature in an environment in which an electronic device to which the semiconductor integrated circuit device 110b is applied is used, and the like.

For example, use of the wireless sensor network terminal 110 on which the semiconductor integrated circuit device 110b is mounted in various environments may be assumed, and specifically, the standby power P4 largely changes due to a temperature in an environment that surrounds the wireless sensor network terminal 110.

In this case, for example, there is a probability that an intermittent operation of the wireless sensor network terminal 110 largely changes over time, and also, there is a probability that the amount of data of the wireless sensor network terminal 110 and the frequency of wireless communication with the base station 140 largely change.

Therefore, it is difficult to control a memory such that respective power consumptions of the semiconductor integrated circuit device 110b (a processor system) and the wireless sensor network terminal 110 on which the semiconductor integrated circuit device 110b is mounted are reduced.

Note that this problem is not limited to a semiconductor integrated circuit device that is applied to a wireless sensor network terminal, but similarly arises in a semiconductor integrated circuit device that is applied to various electronic devices for which low power consumption is desired to be achieved.

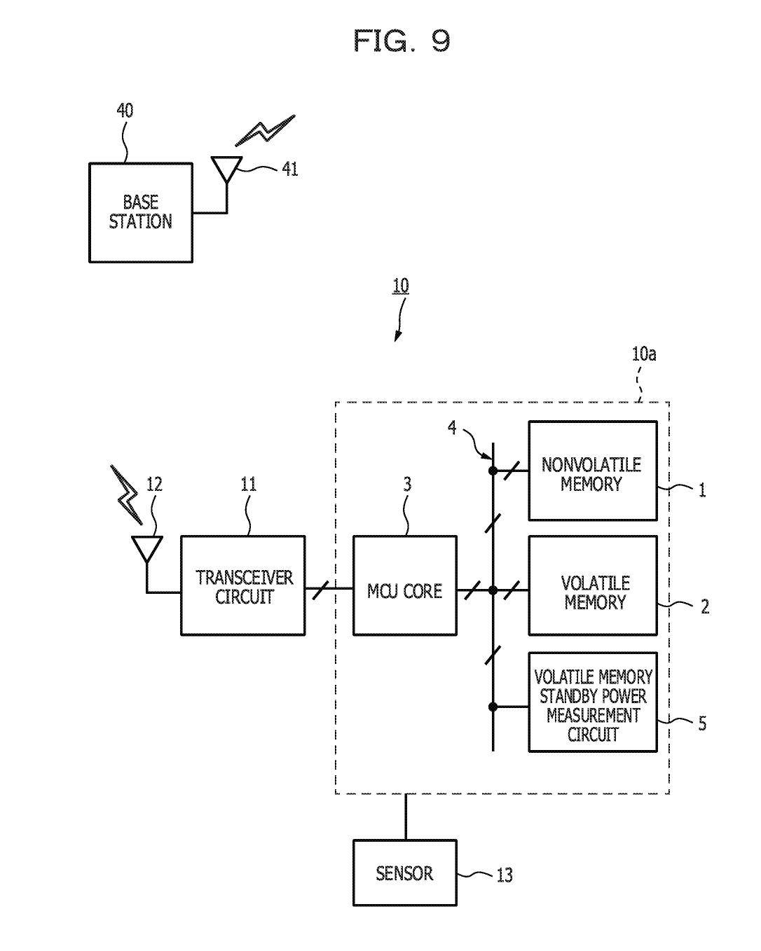

Embodiments related to a semiconductor integrated circuit device, a wireless sensor network terminal, and a memory control method for the semiconductor integrated circuit device will be described below with reference to the accompanying drawings. FIG. 9 is a block diagram illustrating a wireless sensor network terminal to which a semiconductor integrated circuit device according to a first embodiment is applied.

As illustrated in FIG. 9, a semiconductor integrated circuit device 10a according to the first embodiment includes a nonvolatile memory 1, a volatile memory 2, an MCU core 3, a bus 4, and a volatile memory standby power measurement circuit 5. Although, in this case, the nonvolatile memory 1 is, for example, a NAND-type flash memory, the nonvolatile memory 1 may be a NOR-type flash memory, and furthermore, a nonvolatile memory other than a flash memory may be employed.

Also, although the volatile memory 2 is, for example, an SRAM, the volatile memory 2 is not limited to the SRAM, and may be a volatile memory (for example, a dynamic random access memory (DRAM)) which may be randomly accessed. Note that the nonvolatile memory 1, the volatile memory 2, the MCU core 3, and the volatile memory standby power measurement circuit 5 are coupled to one another via the bus 4.

That is, as clearly understood from comparison between FIG. 9 and FIG. 3 described above, the semiconductor integrated circuit device 10a according to the first embodiment has a configuration obtained by further providing the volatile memory standby power measurement circuit 5 in the semiconductor integrated circuit device 110b illustrated in FIG. 3.

As illustrated in FIG. 9, a wireless sensor network terminal 10 to which the semiconductor integrated circuit device 10a according to the first embodiment includes the semiconductor integrated circuit device 10a described above, a transceiver circuit 11 to which an antenna 12 is coupled, and a sensor 13.

The wireless sensor network terminal 10 wirelessly transmits, for example, measurement data (information), such as a temperature and the like, measured by the sensor 13 to a base station 40, to which an antenna 41 is coupled, via the transceiver circuit 11 and the antenna 12.

In this case, in the semiconductor integrated circuit device 10a, for example, the power consumption of the nonvolatile memory 1 during an operation is easy to predict because the power consumption is based on a current during a circuit operation and a leakage current of a transistor, such as a standby power and the like, is not dominant, and also, the power consumption of the volatile memory 2 during an operation is similarly easy to predict.

In contrast, the power consumption of the volatile memory 2 during a standby state, that is, the power consumption (P4) based on a leakage current generated when the power of the volatile memory 2 is maintained in an on state, largely changes due to fabrication variations of the semiconductor integrated circuit device 10a and environmental variations, such as variations in temperature and the like, because a leakage current of a transistor is dominant. Therefore, as described above, the standby power P4 is difficult to predict.

In the semiconductor integrated circuit device 10a according to the first embodiment, the volatile memory standby power measurement circuit 5 is provided, the standby power consumption (the standby power P4) of the volatile memory 2 is measured by the volatile memory standby power measurement circuit 5, and thus, memory control is performed.

As described above, the semiconductor integrated circuit device 10a according to this embodiment may be configured to include the transceiver circuit 11. Also, needless to say, the semiconductor integrated circuit device 10a according to this embodiment may be also widely applied to various other electronic devices as well as the wireless sensor network terminal 10.

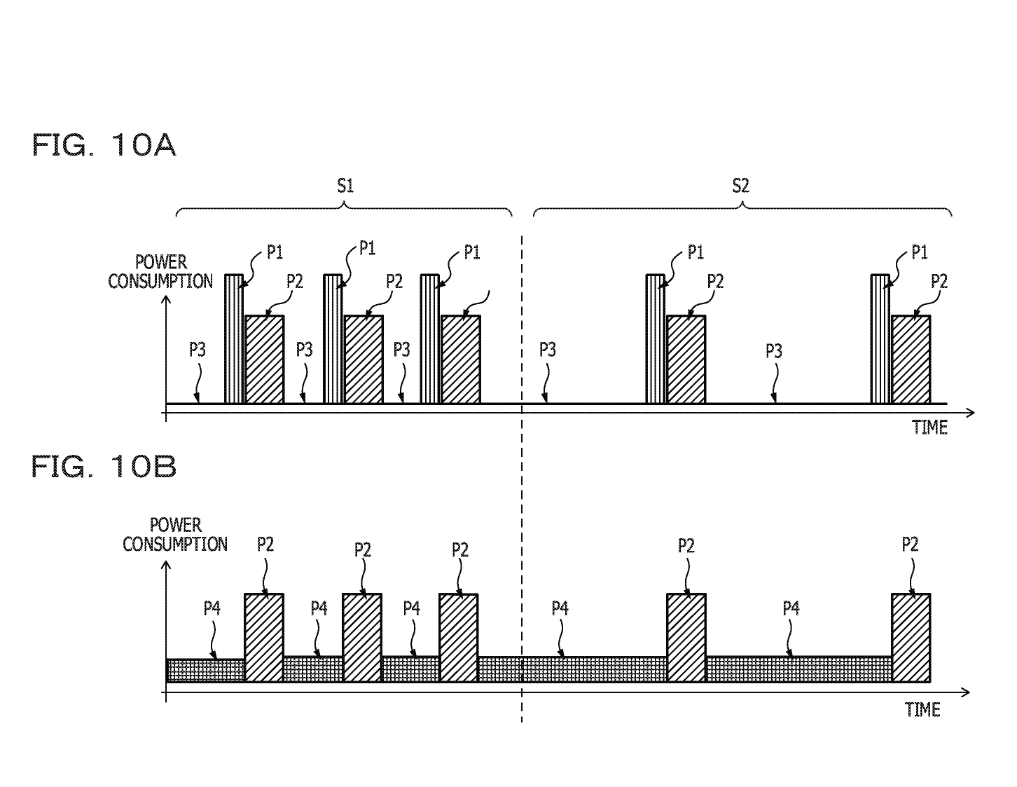

FIG. 10A and FIG. 10B are charts illustrating an operation of the wireless sensor network terminal illustrated in FIG. 9, and FIG. 10A and FIG. 10B correspond to FIG. 8A and FIG. 8B described above, respectively. Note that, in FIG. 10A and FIG. 10B, the reference character S1 denotes a state where operation frequency (the frequency of wireless communication with the base station 40) is high over time, and the reference character S2 denotes a state where the operation frequency is low over time.

According to the first embodiment, the standby power P4 of the volatile memory 2 is measured by the volatile memory standby power measurement circuit 5, and thus, the average power consumption P1+P2+P3 illustrated in FIG. 10A and the average power consumption P4+P2 illustrated in FIG. 10B may be correctly compared with each other.

That is, if P1+P2+P3>P4+P2 is satisfied, for example, the state 51 is determined, the power of the volatile memory 2 is maintained in an on state, and thus, data of the volatile memory 2 is held (a first mode).

However, when an initial operation is started (when the power of the volatile memory 2 is switched from off to on), a program is not stored in the volatile memory 2, and therefore, the memory access power P1 for reading out a program from the nonvolatile memory 1 to the volatile memory 2 is consumed.

On the other hand, if P1+P2+P3<P4+P2 is satisfied, for example, the state S2 is determined, each time an operation is performed (each time wireless communication is performed), a program is read out from the nonvolatile memory 1 to the volatile memory 2 and, when the processing is terminated, control is performed such that the power of the volatile memory 2 is turned off (a second mode).

Note that, although the sleep power P3 may be made very small by turning off the power of the volatile memory 2, data (a program) held by the volatile memory 2 is erased. Also, if P1+P2+P3=P4+P2 is satisfied, this result may be included either one of the first mode and the second mode.

As described above, according to this embodiment, the standby power P4 of the volatile memory 2 is measured by the volatile memory standby power measurement circuit 5, and thus, when an operation is started, whether or not data is read out from the nonvolatile memory 1 again is controlled by maintaining the power of the volatile memory 2 in an on state or putting the power of the volatile memory 2 in an off state.

That is, both of the average power consumptions (P1+P2+P3 and P2+P4: power consumptions over time) are compared with each other, and one of the average power consumptions, which is smaller, is selected, thereby allowing reduction in power consumption for an intermittent operation as a whole.

In this case, because the sleep power P3 is very small, substantially, for example, the memory access power P1 and the standby power P4 are compared with each other, and, over time, if P1 is larger than P4, the volatile memory 2 is maintained in an on state, while, if P4 is larger than P1, the volatile memory 2 is turned off.

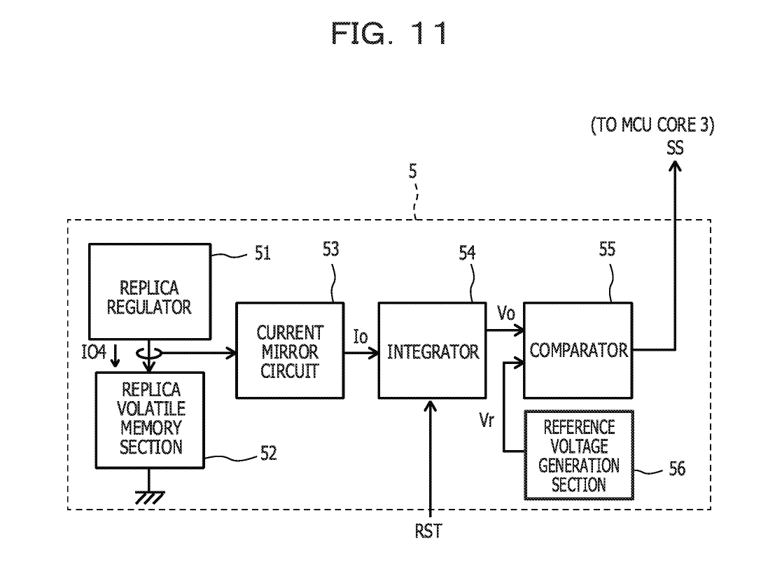

FIG. 11 is a block diagram illustrating an example volatile memory standby power measurement circuit in the semiconductor integrated circuit device illustrated in FIG. 9. As illustrated in FIG. 11, the volatile memory standby power measurement circuit 5 includes a replica regulator 51, a replica volatile memory section 52, and a current mirror circuit (a first current mirror circuit) 53. Furthermore, the volatile memory standby power measurement circuit 5 further includes an integrator (a first integrator) 54, a comparator (a first comparator) 55, and a reference voltage generation section (a first reference voltage generation section) 56.

The replica regulator 51 is provided to cause a current to flow in the replica volatile memory section 52, which is a replica of an actual volatile memory section (22) in the volatile memory 2.

In this case, for example, considering power consumption, in order to reduce the influence of transistor fabrication variations, the replica volatile memory section 52 may include a plurality of memory cells (SRAM cells) (of about one hundredth of the number of the actual volatile memory sections 22).

Thus, a current I04 flowing from the replica regulator 51 to the replica volatile memory section 52, which corresponds to a current (a leakage current, the standby current I4) that flows in the actual volatile memory section 22 when the power of the volatile memory 2 is maintained in an on state, is detected by the current mirror circuit 53.

That is, a current (the standby current I04) flowing in the volatile memory 2 in a standby state, which is difficult to predict due to fabrication variations and environmental variations, is measured by the replica regulator 51, the replica volatile memory section 52, and the current mirror circuit 53.

Furthermore, electric charges generated by an output current To (for example, a current equal to I04) of the current mirror circuit 53 is integrated (electric charges are accumulated) by the integrator 54, and an output voltage Vo of the integrator 54 and a reference voltage Vr generated by the reference voltage generation section 56 are compared with each other by the comparator 55.

Then, for example, when the output voltage Vo of the integrator 54 exceeds the reference voltage Vr, the comparator 55 outputs a mode switching signal SS to the MCU core 3, and the MCU core 3 determines, for example, the state S2 in FIG. 10A and FIG. 1013 and thus turns off the power of the volatile memory 2.

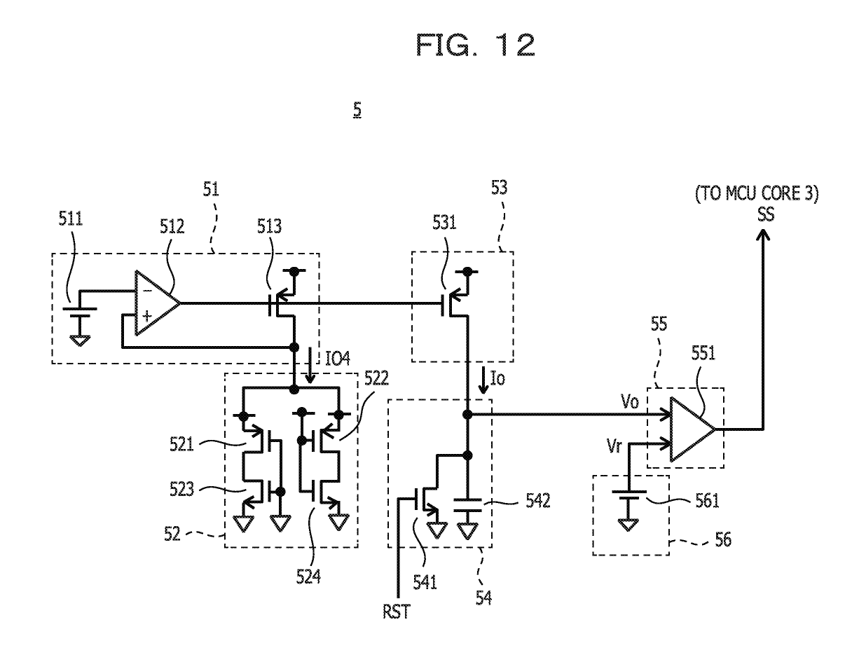

FIG. 12 is a circuit diagram illustrating the example volatile memory standby power measurement circuit illustrated in FIG. 11. As illustrated in FIG. 12, the replica regulator 51 includes a voltage source 511, an operation amplifier 512, and a p-channel type MOS (p-MOS) transistor 513. The replica volatile memory section 52 includes p-MOS transistors 521 and 522 and n-channel type MOS (n-MOS) transistors 523 and 524.

In this case, the transistors 521 to 524 form a pseudo SRAM cell. That is, two gate transistors that are selected by word lines are omitted, and a single SRAM cell is artificially formed by four transistors.

Note that, although, in FIG. 12, the replica volatile memory section 52 is illustrated as a single pseudo SRAM cell, as described above, in order to reduce the influence of transistor fabrication variations, considering power consumption, it is preferable that a plurality of replica volatile memory sections 52 is provided.

The current mirror circuit 53 includes, for example, a p-MOS transistor 531 having the same size as that of the transistor 513, and the current 104 flowing in the transistor 513 is mirrored by the transistor 531 to cause the current Io to flow in the integrator 54. Note that, needless to say, the size of the transistor 531 is not limited to the same size as that of the transistor 513.

The integrator 54 includes an n-MOS transistor 541 and a capacitor 542, and accumulates electric charges generated by the current Io flowing in the transistor 531 in the capacitor 542. Note that the transistor 541 is provided to reset electric charges accumulated in the capacitor 542, makes a reset signal RST a high level “H” to cause an on state, and thus, discharges the electric charges accumulated in the capacitor 542.

Then, for example, after the power of the volatile memory 2 is turned off, the reset signal RST is output at the timing at which a program is read out again from the nonvolatile memory 1 to the volatile memory 2 and is held therein, the MCU core 3 executes the program, and the processing is completed, or like timing.

The reference voltage generation section 56 includes a voltage source 561, generates the reference voltage Vr, and outputs the reference voltage Vr to the comparator 55. The comparator 55 (551) compares the output voltage Vo of the integrator 54 with the reference voltage Vr and outputs, if the voltage Vo is higher than the reference voltage Vr, a control signal (output) SS to the MCU core 3.

The MCU core 3 receives the control signal SS from the volatile memory standby power measurement circuit 5 and, for example, turns off the power of the volatile memory 2, which has been maintained in an on state until then. Thus, the program held in the volatile memory 2 is erased, and power consumed by the semiconductor integrated circuit device 10a is changed to the standby power P1, which is smaller than the sleep power P4.

When a wireless communication operation is performed next, for example, a program is read out from the nonvolatile memory 1 to the volatile memory 2, and then, the MCU core 3 executes the program on the volatile memory 2.

As described above, the volatile memory standby power measurement circuit 5 according to the first embodiment may reduce the influence on the actual volatile memory 2 to a minimum level and perform memory control by detecting the standby current I04 of the replica volatile memory section 52, which corresponds to the standby current I4 of the volatile memory 2.

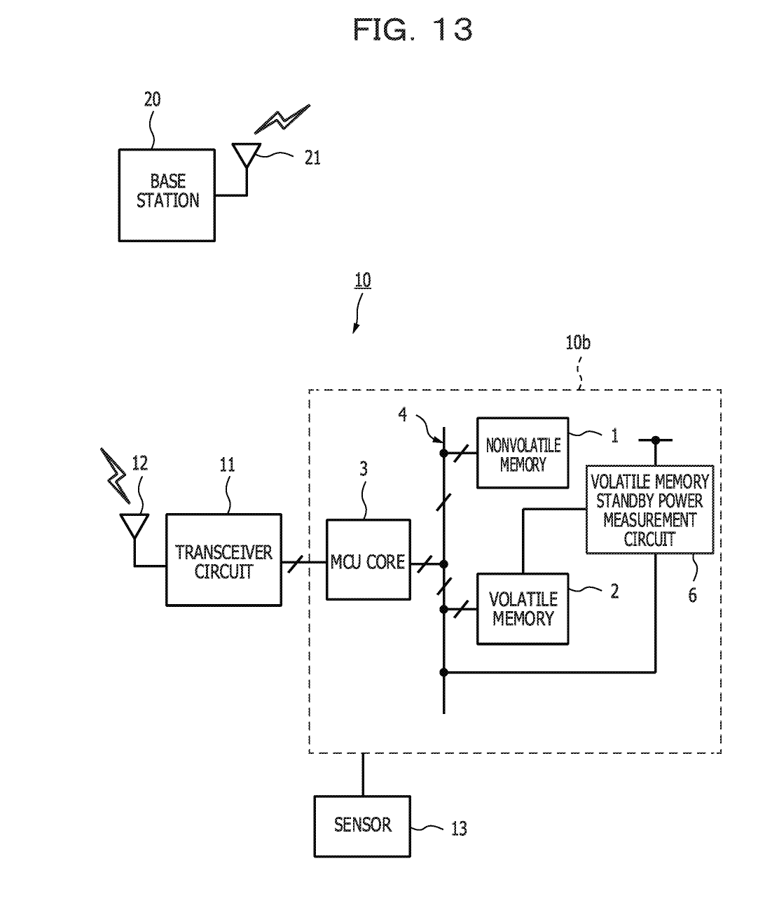

FIG. 13 is a block diagram illustrating a wireless sensor network terminal to which a semiconductor integrated circuit device according to a second embodiment is applied and, in FIG. 13, a volatile memory standby power measurement circuit 6 is provided between the actual volatile memory 2 and a power line.

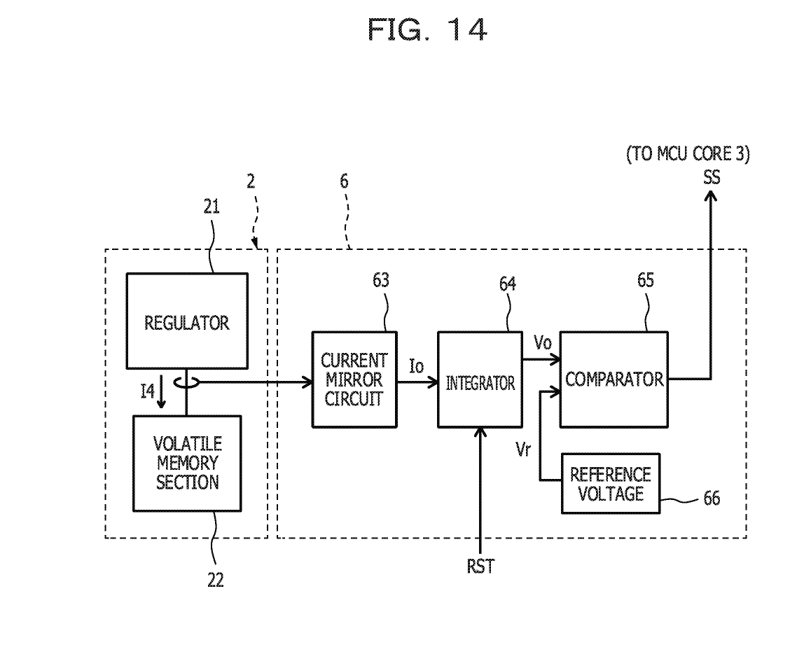

FIG. 14 is a block diagram illustrating an example volatile memory standby power measurement circuit in the semiconductor integrated circuit device illustrated in FIG. 13. As illustrated in FIG. 14, the volatile memory standby power measurement circuit 6 includes a current mirror circuit (a second current mirror circuit) 63, an integrator (a second integrator) 64, a comparator (a second comparator) 65, and a reference voltage generation section (a second reference voltage generation section) 66.

The current mirror circuit 63 detects the current I4 flowing from a regulator 21 in the volatile memory 2 to the volatile memory section 22 by mirroring. That is, in the semiconductor integrated circuit device according to the second embodiment, the current mirror circuit 63 detects the standby current I4 in the actual volatile memory 2. Note that the configurations of other members are similar to those in the first embodiment illustrated in FIG. 11.

That is, the integrator 64 accumulates (integrates) electric charges generated by the output current Io (for example, a current equal to I4) of the current mirror circuit 63, and the comparator 65 compares the output voltage Vo of the integrator 64 and the reference voltage Vr generated by a reference voltage generation section 66 with each other.

Then, for example, when the output voltage Vo of the integrator 64 exceeds the reference voltage Vr, the comparator 65 outputs the mode switching signal SS to the MCU core 3, and the MCU core 3 determines, for example, the state S2 in FIG. 10A and FIG. 1013, and turns off the power of the volatile memory 2.

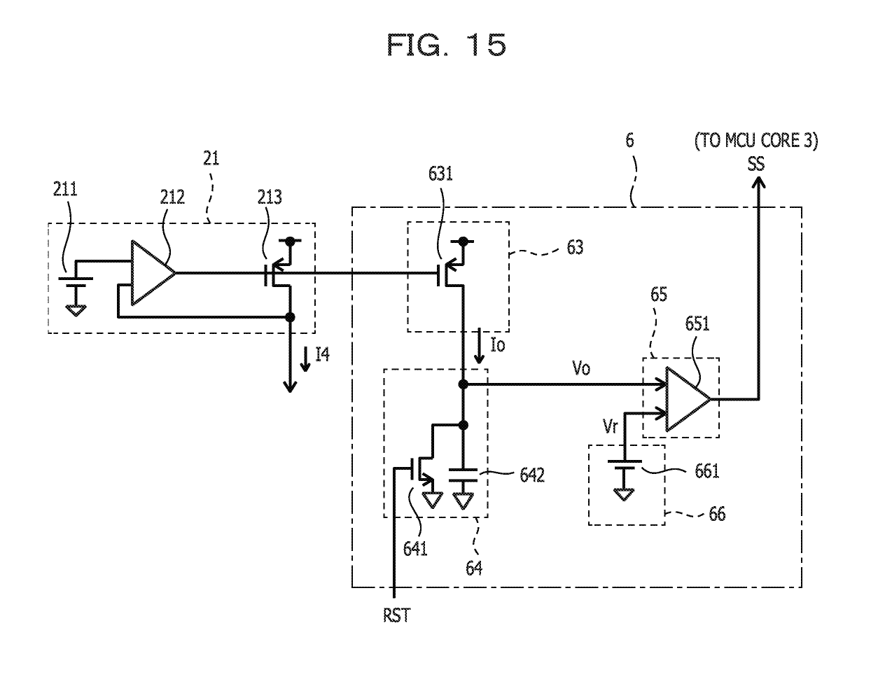

FIG. 15 is a circuit diagram illustrating the example volatile memory standby power measurement circuit illustrated in FIG. 14. Note that, in FIG. 15, the volatile memory standby power measurement circuit 6 is illustrated with the regulator 21 in the volatile memory 2.

As illustrated in FIG. 15, the regulator 21 includes a voltage source 211, an operation amplifier 212, and a p-MOS transistor 213. Note that the regulator 21 is provided to supply power to the actual volatile memory section 22.

The current mirror circuit 63 includes, for example, a p-MOS transistor 631 having a smaller size than that of the transistor 213, and is configured such that the current I4 flowing in the transistor 213 is mirrored by the transistor 631 to cause the current Io corresponding to the ratio of the transistor size to flow in the integrator 64.

Note that the size (the gate width) of the transistor 631 may be set, for example, such that a current corresponding to the current Io in FIG. 12, which is described above, flows, based on the ratio of the size of the transistor 631 to the size of the transistor 213.

The integrator 64 includes an n-MOS transistor 641 and a capacitor 642, and accumulates electric charges generated by the current Io flowing in the transistor 631 in the capacitor 642. Note that the transistor 641 is provided to reset electric charges accumulated in the capacitor 642, makes the reset signal RST a high level “H” to cause an on state, and thus, discharges the electric charges accumulated in the capacitor 642.

Then, for example, after the power of the volatile memory 2 is turned off, the reset signal RST is output at the timing at which a program is read out again from the nonvolatile memory 1 to the volatile memory 2 and is held therein, the MCU core 3 executes the program, and the processing is completed, or like timing.

The reference voltage generation section 66 includes a voltage source 661, generates the reference voltage Vr, and outputs the reference voltage Vr to the comparator 65. The comparator 65 (651) compares the output voltage Vo of the integrator 64 with the reference voltage Vr and outputs, if the voltage Vo is higher than the reference voltage Vr, a control signal (output) SS to the MCU core 3.

The MCU core 3 receives the control signal SS from the volatile memory standby power measurement circuit 6 and, for example, turns off the power of the volatile memory 2, which has been maintained in an on state until then. Thus, the program held in the volatile memory 2 is erased and power consumed by a semiconductor integrated circuit device 10b is the standby power P1, which is smaller than the sleep power P4.

When wireless communication operation is performed next, for example, a program is read out from the nonvolatile memory 1 to the volatile memory 2, and then, the MCU core 3 executes the program on the volatile memory 2. As described above, the volatile memory standby power measurement circuit 6 in the second embodiment performs memory control by detecting the standby current I4 of the actual volatile memory 2.

Needless to say, the above-described first and second embodiments are merely examples and various modifications and changes may be made. Also, the semiconductor integrated circuit devices 10a and 10b in the above-described embodiments are not limit to application to a wireless sensor network terminal and may be widely used in various electronic devices.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A device comprising:
a nonvolatile memory configured to store data;
a volatile memory configured to store the data read out from the nonvolatile memory;
a processor configured to perform processing using the data stored in the volatile memory; and
a measurement circuit configured to measure standby power of the volatile memory when the power of the volatile memory is turned on,
wherein
the processor is configured to control, based on a measurement result outputted from the measurement circuit, power supply to the volatile memory while the processor is to be intermittently operated.

2. The device according to claim 1, wherein
the processor is configured to switch, based on the measurement result outputted from the measurement circuit, between
a first mode in which the power of the volatile memory is maintained in an on state and, when the processor performs next processing, the data continuously stored in the volatile memory is used by the processor, and
a second mode in which the power of the volatile memory is turned off and, when the processor performs next processing, the power of the volatile memory is turned on, the data stored in the nonvolatile memory is read out and is stored in the volatile memory again, and the data stored in the volatile memory is used by the processor.

3. The device according to claim 2, wherein
the processor is configured to
compare memory access power used for reading out the data stored in the nonvolatile memory and storing the data to the volatile memory, and the standby power of the volatile memory which is measured by the measurement circuit, with each other,
select the first mode when the memory access power is larger than the standby power based on the comparison, and
select the second mode when the memory access power is smaller than the standby power based on the comparison.

4. The device according to claim 3, wherein
the measurement circuit includes
a replica volatile memory circuit corresponding to a volatile memory circuit of the volatile memory,
a replica regulator configured to supply power to the replica volatile memory circuit,
a first current mirror circuit configured to detect a current flowing in the replica volatile memory circuit from the replica regulator,
a first integrator configured to integrate an output of the first current mirror circuit, and
a first comparator configured to compare an output voltage of the first integrator with a reference voltage and to output a control signal to the processor when the output voltage of the first integrator exceeds the reference voltage, and
the processor is configured to switch, based on the control signal, from the first mode to the second mode.

5. The device according to claim 4, wherein the replica volatile memory circuit includes a plurality of memory cells.

6. The device according to claim 3, wherein
the volatile memory includes
a volatile memory circuit, and
a regulator configured to supply power to the volatile memory circuit,
the measurement circuit includes
a second current mirror circuit configured to detect a current flowing in the volatile memory circuit from the regulator,
a second integrator configured to integrate an output of the second current mirror circuit, and
a second comparator configured to compare an output voltage of the second integrator with a reference voltage and to output a control signal to the processor when the output voltage of the second integrator exceeds the reference voltage, and
the processor is configured to switch, based on the control signal, from the first mode to the second mode.

7. The device according to claim 1, wherein
the nonvolatile memory is a flash memory, and
the volatile memory is a static random access memory.

8. The device according to claim 7, wherein
the nonvolatile memory is a NAND-type flash memory.

9. The device according to claim 1, wherein
the data read out from the nonvolatile memory and stored in the volatile memory includes data of a program that is executed by the processor.

10. A wireless sensor network terminal device comprising:
the device according to claim 1;
a sensor configured to collect information; and
a transceiver circuit configured to intermittently perform communication with a base station and transmit information acquired by the sensor to the base station.

11. The wireless sensor network terminal device according to claim 10, wherein
an interval of the communication performed with the base station is controlled to be short when the amount of the information acquired by the sensor is large, and be long when the amount of the information acquired by the sensor is small.

12. A memory control method for a device including a nonvolatile memory that stores a program, a volatile memory configured to store the program read out from the nonvolatile memory, and a processor configured to execute the program read out from the volatile memory, the memory control method comprising:
maintaining, by the processor after the processor executes the program and completes processing, the power of the volatile memory that stores the program therein in an on state;
measuring, by the processor, standby power of the volatile memory the power of which is maintained in an on state; and
controlling, by the processor and based on the measured standby power of the volatile memory, power supply to the volatile memory while the processor is to be intermittently operated.

13. The memory control method according to claim 12, further comprising:
switching, by the processor and based on the measured standby power,
a first mode in which the power of the volatile memory is maintained in an on state and, when the arithmetic processing unit performs next processing, the data continuously stored in the volatile memory is used by the processor, and
a second mode in which the power of the volatile memory is turned off and, when the arithmetic processing unit performs next processing, the power of the volatile memory is turned on, the data stored in the nonvolatile memory is read out and is stored in the volatile memory again, and the data stored in the volatile memory is used by the processor.

14. The memory control method according to claim 13, further comprising:
comparing, by the processor, memory access power used for reading out the data stored in the nonvolatile memory and storing the data to the volatile memory and the standby power with each other;
selecting, by the processor, the first mode, when the memory access power is larger than the standby power based on the comparison; and
selecting, by the processor, the second mode, when the memory access power is smaller than the standby power based on the comparison.

15. The memory control method according to claim 12, wherein
the nonvolatile memory is a flash memory, and
the volatile memory is a static random access memory.
